(19) United States
(12) Patent Application Publication
(10) Pub. No.: US 2008/0168339 A1
(43) Pub. Date: Jul. 10, 2008

(54) SYSTEM AND METHOD FOR AUTOMATIC ENVIRONMENTAL DATA VALIDATION

(75) Inventors: Peter Hudson, Vancouver (CA); Touraj Farahmand, Burnaby (CA); Edward J. Quilty, Vancouver (CA)

Correspondence Address: GOWLING LAFLEUR HENDERSON LLP (OTT), SUITE 2600, 160 ELGIN STREET, OTTAWA, ON, K1P1C3, omitted

(73) Assignee: Aquatic Informatics (139811), Vancouver (CA)

(21) Appl. No.: 11/958,129

(22) Filed: Dec. 17, 2007

Related U.S. Application Data
(60) Provisional application No. 60/876,693, filed on Dec. 21, 2006.

(51) Int. Cl. H03M 13/09; G06F 11/10

(52) U.S. Cl. 714/800; 714/E11.032

(57) ABSTRACT

A method for identifying anomalies in time series data, the method comprising the steps of computing parity vectors for one or more data points in a predetermined sample of data points in the time series, the parity vector representing redundancy between an estimated true value and an error term for each of the said one or more data points, evaluating the parity vectors to determine a set of the parity vectors in a selected direction; and evaluating a statistical distribution of the set according to a predetermined criterion to determine a data point to be corrected whose parity vectors satisfy the criterion in the distribution.

### CROSS-REFERENCE TO RELATED APPLICATIONS

This application claims priority from U.S. Provisional application No. 60/876,693 filed, Dec. 21, 2006, the disclosure of which is incorporated herein by reference in its entirety.

### FIELD

The present invention relates to the field of hydrology and environmental science and more particularly to a system and method for data analysis and modeling incorporating automated data validation.

### BACKGROUND OF THE INVENTION

In the field of hydrology, hydrologists and other environmental scientists apply scientific knowledge and mathematical principles to solve water-related problems such as quantity, quality and availability.

Much of this work relies on computers for organizing, summarizing and analyzing masses of data collected from rivers, water wells and weather stations, and for modeling studies such as the prediction of flooding and the consequences of reservoir releases or for example the effect of leaking underground oil storage tanks. The data is collected in one of two ways, by manual field measurements or by aquatic monitoring sensors. The latter replacing the traditional manual approach which tends not to capture extreme events, such as storms or pollution spills. Furthermore, with the manual approach, field samplers are unlikely to be in the field exactly when such events occur. Moreover, occasional field sampling cannot characterize higher-frequency aquatic processes, such as the diurnal oscillations (DO) of pH and dissolved oxygen that can result from biological activity or temperature.

While monitoring sensors are preferred they can often produce data that may not be representative of actual conditions. For example, optical (turbidity) sensors are prone to record unrealistically high values due to bubble disturbances, wiper brush positioning, or obscurity of the sensor window. Sensors such as pH and dissolved oxygen can be miscalibrated, or if damaged can begin to drift as the control solution becomes contaminated with ambient water. Water level sensors can produce spurious data if the sensor float becomes jammed due to frazil ice or if pressure transducers are improperly calibrated or deployed. Even solid-state sensors, such as thermistors, can record non representative values when exposed to air during low flow periods.

A number of software tools have been produced to aid the hydrologist in the various tasks of organizing, summarizing, analyzing and validating masses of this data. This data can be time series data, discrete sample data or a combination. For example, data validation tools are used to estimate point-by point data uncertainty in time series data, since a series of data points over time (time series data) are only useful if they reflect true conditions, it is necessary to assess the reliability of the time series data.

While, we can often develop considerable analytic redundancy for environmental measurements at a particular sensor at a particular location by using empirical models in conjunction with various other data sources, such as data from other types of sensors at the same location and/or measurements of the same or different water quality parameters at another location, either within the same watershed or, if appropriate, in adjacent catchments, there exists times where no suitable surrogate data can be found or models developed.

Accordingly there is a need for a system and method that simplifies the validation, correction, management and analysis of water quality, hydrology, and climate time-series data.

### SUMMARY OF THE INVENTION

An object of the present invention is to provide a system and method for determining faulty data in a series of data values from a sensor signal using parity-space signal validation.

A further object of the present invention is to identify the faulty data.

In accordance with this invention there is provided a method for identifying anomalies in time series data, said method comprising the steps of: computing parity vectors for one or more data points in a predetermined sample of data points in said time series, the parity vector representing redundancy between an estimated true value and an error term for each of the one or more data points; evaluating the parity vectors to determine a set of parity vectors in a selected direction; and evaluating a statistical distribution of the set according to a predetermined criterion to determine and identify a data point to be corrected whose parity vectors satisfy the criterion in the distribution.

In accordance with a further aspect of the invention there is provided a system comprising: a network of sensors, for sensing one or more environmental conditions and at least one sensor in the network generating at least one time series data sequence; a data validation module associated with at least one sensor in the network for validating the time series data generated by the at least one sensor, by determining a distribution of parity vectors computed on said time series data points and by using redundant data obtained from the network, the distribution being used to identify data points to be validated in the time series.

### BRIEF DESCRIPTION OF THE DRAWINGS

The present invention will be further understood from the following detailed description with reference to the drawings in which:

FIG. 1 is a block diagram of a computer system providing operating environment for an exemplary embodiment of the present invention;

FIG. 2 is a flow chart illustrating data validation according to an embodiment of the invention;

FIG. 3 is a schematic of a typical watershed used to illustrate one aspect of the present invetion;

FIG. 4 is a planar representation of parity space illustrating calculation of a composite noise vector;

FIG. 5 is a graph showing dissolved oxygen readings for each of three sensors over a period of time;

FIG. 6 is a graph showing a distribution of parity vector lengths for a first sensor of FIG. 5;

FIG. 7 is a graph showing validation flags assigned to the reading from the first sensor of FIG. 5;

FIG. 8 is a graph showing an expanded view of the readings from the sensor of FIG. 5 with validation flags; and

FIG. 9 is a detailed flow chart illustrating data validation according to an embodiment of the invention.

### DETAILED DESCRIPTION OF THE PREFERRED EMBODIMENTS

In the following description like numerals refer to like structures in the drawings.

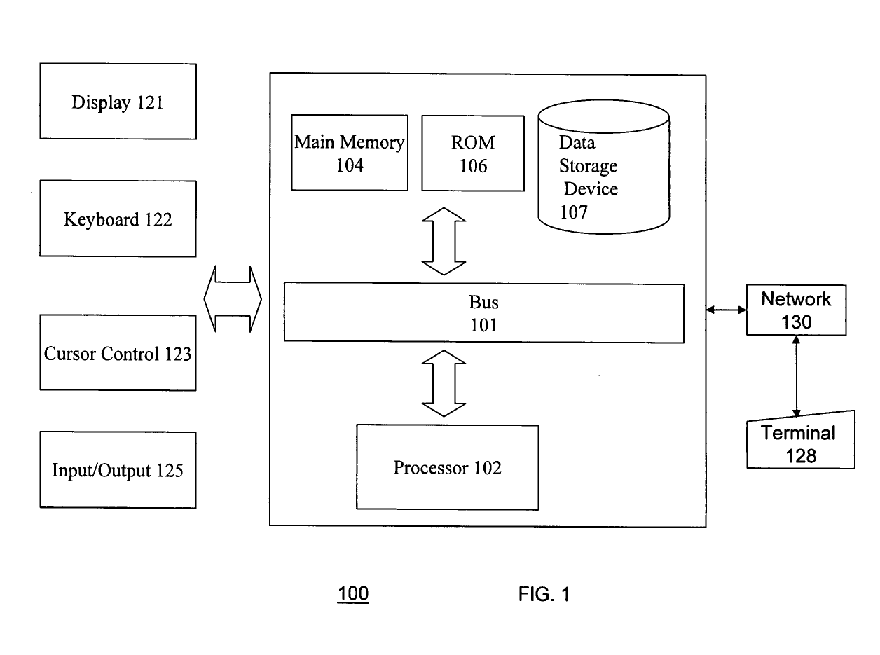

Referring to FIG. 1 there is shown a computer system 100 for implementing a hydrological data processing system according to an embodiment of the present invention. The computer system 100 comprises a machine-readable medium to contain instructions that, when executed, cause a machine to execute a hydrological data validation processes as described below. Other instructions may cause a machine to perform any of the methods below including the display of a user interface for initiating, manipulating and interacting with the data validation process. The system 100 may comprise a bus or other communication means 101 for communicating information, and a processing means such as processor 102 coupled with bus 101 for processing information. The system 100 further comprises a random access memory (RAM) or other dynamically generated storage device 104 (referred to as main memory), coupled to bus 101 for storing information and instructions to be executed by processor 102. Main memory 104 also may be used for storing temporary variables or other intermediate information during execution of instructions by processor 102. The system 100 also comprises a read only memory (ROM) and/or other static storage device 106 coupled to bus 101 for storing static information and instructions for processor 102. A data storage device 107 such as a magnetic disk or optical disk and its corresponding drive may also be coupled to with the system 100 for storing information and instructions. A display device 121 is coupled via a the bus, for displaying information to an end user. Typically, an alphanumeric input device (keyboard) 122, may be coupled to bus 101 for communicating information and/or command selections to processor 102. Another type of user input device is cursor control 123, such as a mouse, a trackball, or cursor direction keys for communicating direction information and command selections to processor 102 and for controlling cursor movement on display 121. Some embodiments may have detachable interfaces such as display 121 a touch screen, keyboard 122, cursor control device 123, and input/output device 122 or may only use a portion of the detachable devices. An input/output device 125 is also coupled to bus 101. The input/output device 125 may include interrupts, ports, modem, a network interface card, or other well-known interface devices, such as those used for coupling to Ethernet, token ring, or other types of physical, wireless, and infrared or other electromagnetic mediums for purposes of providing a communication link. In this manner, the system 100 may be networked with a number of clients, servers, or other information devices. The system may also be accessed by a terminal 128 via a network 130. Furthermore, the input/output device 125 may be coupled to one or more sensors to measure features of a test fluid. In an aquatic monitoring system, example sensors may include optical turbidity sensors, pH sensors, dissolved oxygen sensors, water level sensors, temperature sensors, solid-state sensors (thermistor), etc. The information or data provided by the sensors may be meta-data, or other information derived from a data set, and is not limited to the data itself.

The system 100 is not limited to a single computing environment. Moreover, the architecture and functionality of embodiments as taught herein and as would be understood by one skilled in the art is extensible to other types of computing environments and embodiments in keeping with the scope and spirit of this disclosure. Embodiments provide for various methods, computer-readable mediums containing computer-executable instructions, and apparatus. With this in mind, the embodiments discussed herein should not be taken as limiting the scope of this disclosure; rather, this disclosure contemplates all embodiments as may come within the scope of the appended claims.

Embodiments include various operations, which will be described below. The operations, may be performed by hard-wired hardware, or may be embodied in machine executable instructions that may be used to cause a general purpose or special purpose processor, or logic circuits programmed with the instructions to perform the operations. Alternatively, the operations may be performed by any combination of hard-wired hardware, and software driven hardware. Embodiments may be provided as a computer program that may include a machine-readable medium, stored thereon instructions, which may be used to program a computer (or other programmable devices) to perform a series of operations according to embodiments of this disclosure and their equivalents. The machine-readable medium may include, but is not limited to, floppy diskettes, optical disks, CD-ROM's, DVD's, mgneto-optical disks, ROM's, RAM'S, EPROM's, EEPROM's, flash memory, hard drives, magnetic or optical cards, or any other medium suitable for storing electronic instructions. Moreover, embodiments may also be downloaded as a computer software product, wherein the software may be transferred between programmable devices by data signals in a carrier wave or other propagation medium via a communication link (e.g. a modem or a network connection).

Exemplary system 100 may implement an apparatus comprising a machine-readable medium to contain instructions that, when executed, cause a machine to perform the automated data validation described. Other instructions may cause a machine to perform any of the methods described in this detailed description.

In accordance with an embodiment of the invention there is provided a system for identifying anomalies in time series data, said system comprising: a first module for computing parity vectors for a data points in a predetermined sample of data points in said time series, the parity vector representing redundancy between an estimated true value and an error term for each said data points; a second module for evaluating said parity vectors to determine a set of said parity vectors in a selected direction; and a third module for evaluating a statistical distribution of the set according to a predetermined criterion to determine a data point to be corrected whose parity vectors satisfy said criterion in said distribution. The modules as described may be implemented in one or memories of the system 100.

By way of background it is understood that, in the field of environmental data analysis, complete elimination of problems in the operation of automated monitoring stations is not logistically feasible using current data collection technologies. Additionally even a station in perfect working order may deliver corrupted data if electromagnetic activity in the ionosphere reduces the quality of satellite or short wave radio transmissions. Since data series are only useful if they actually reflect true conditions, it behooves the collector of time series data to assess the reliability of the data. Broadly, the ultimate concern is estimating point-by-point data uncertainty.

Typically, a sparse array of sensors and monitoring stations record data that are intended to characterize an environmental system. For clarity and ease of explanation the following description will refers specifically to a specific type of environmental system such as an aquatic system. For example in aquatic systems; either after the data is collected or in real-time, researchers and managers need to determine whether the data is representative of actual water quality conditions. Additionally, models may exist to predict water quality conditions in a target natural environment, developed either from empirical observation of the target natural environment, from theoretical modelling applied to the target natural environment, or some combination of theory and empirical observation of the target natural environment, which can provide synthetic data to compare to actual sensor data.

While it is possible for validation of data by using historical data from the same station. A problem with using historical data in the validation of, for example, hydrometric data is that datasets tend to be much shorter. Given a five year dataset, to validate any given year of data our historical range and mean are constructed from only four peer data points, which is unusably small distribution.

Accordingly, the present invention avoids the problems of unusable small distributions by using a distribution related to parity space vectors rather than peer data points. As such the number of data points in the time series being validated all form a single distribution from which outliers, faults and other errors can be identified.

A parity space method as outlined in Ray, A. and Luck, R., 2001. “An Introduction to Sensor Signal Validation in Redundant Measurement Systems.” IEEE Control Systems. February: 44-49 incorporated herein by reference, is used to generate parity vectors used in the below analysis of time series data according to an embodiment of the present invention.

The data validation method of the present invention adapts the parity space method to the problem of environmental data validations, as for example aquatic data validation; by adjusting the phase between distant sensors to account for water travel time, by regression to remove offset and system response magnification or attenuation, by using historical data folded year over year where no suitable surrogate data for physical or analytic redundancy is available, and by using a distribution, such as gamma distribution, of the parity vectors, preferably their magnitudes, to assign point-by-point data validation flags.

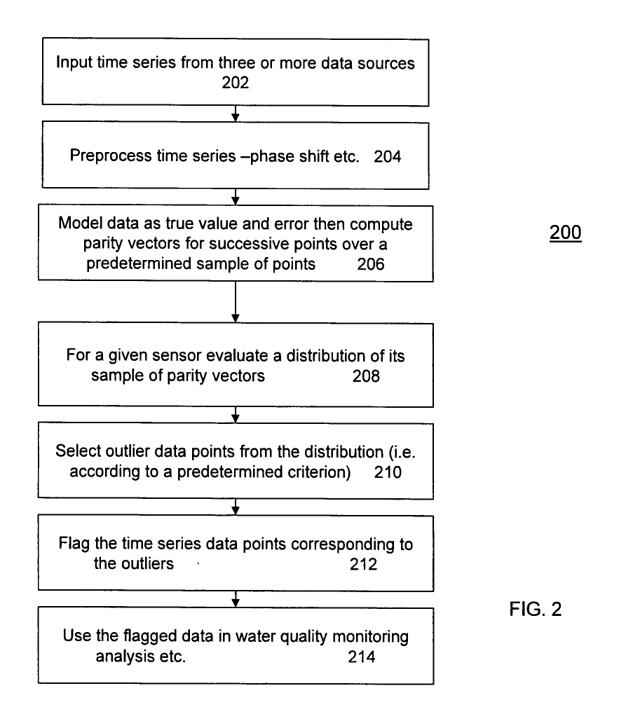

Referring to FIG. 2 there is shown a flow chart describing the a general process 200 for data validation according to an embodiment of the present invention. In general, the process 200 begins with the input 202 of time series data from three or more sources of data, be the sources sensors in the natural environment providing real data from or predictive models providing synthetic data, representing for example the measured value of a water quality parameter. This data may be preprocessed in step 204 as will be discussed later. Next the process 200 continues with the specification of a mathematical model decomposing the measured value of a water quality data parameter from a sensor, which we wish to validate, into its true value and an error term 206. The model is manipulated to yield parity vectors as described in Ray, A. and Luck, R., 2001. “An Introduction to Sensor Signal Validation in Redundant Measurement Systems.” IEEE Control Systems. February: 44-49 and incorporated herein by reference.

The size and direction of the parity vector provides a description of the probability of data faults and the sensors causing the faults. There is one parity vector calculated for each data point of the time series. A statistical method is then used for selecting 210 and assigning a data validation flag 212 to each data point by examining the distribution of the parity vector magnitudes 208. The flagged data point(s) may then be used for analysis 214 of the measured conditions.

The process 200 may be explained by referring to the following description. Referring ahead to step 206 in the process 200 of FIG. 2, the measurement model for the sensors is adapted from a continuously monitored data model defined as follows:

m(t)=H·x(t)+ε(t) (1)

Where x(t) is the actual condition of the parameter being measured by the sensor assuming no error in the signal. A transfer coefficient H contains the level of redundancy of measurement in the monitored system. For parametrs which are vector measurements i.e. containing information such as direction (such as velocity) H may also contain information relating changes of co-ordinate systems from the co-ordinate system of the sensors physical axes to the co-ordinate system of the measurement axes. In general H is a second order tensor, however, in the special case of redundant scalar measurements (which we are principally concerned with in water quality) H=[1 1 . . . 1]^{T}; where the number of entries in H is the order of redundancy of the sensors (both physical, analytic, and historical). The order of redundancy is the total number of time series available, each representing, directly (physical) or indirectly (analytical), the same condition (an example would be three temperature sensors monitoring temperature in one room). The measurement m(t) of equation (1) also includes a term for the measurement error ε(t). This term contains both random noise, assumed to be Gaussian and white, and gross errors due to sensor miscalibration, sensor damage, etc. Since we are always dealing with time series in this description, the symbol t can be dropped for the sake of clarity in the derivation.

Then a linear function f is defined that will be maximally a function of the error term ε and minimally a function of the ideal measurement H·x. That is, the function f is chosen such that f(H·x)=0:

f(m)=f(H·x+ε)=f(H·x)+f(ε)=f(ε) (2)

It is desirable for f to be linear for two reasons. First, linearity allows application of f across the addition in equation (2) to isolate f(ε). Second is that if f is a linear operator, it can be represented as a matrix multiplication. Formulating the function as a matrix multiplication is convenient for constructing a vector space in which erroneous data are separated from good measurements. Thus defining:

v^{T}Ω=f(Ω) (3)

where both v^{T} and f are functions of a dummy variable, Ω and combining equation (2) and equation (3) gives:

v^{T}m=v^{T}(H·x+ε)=v^{T}H·x+v^{T}ε (4)

Since it is desired to have:

v^{T}m=v^{T}ε (5)

set:

v^{T}H·x=0 (6)

That is, v^{T} must span the left null space of H.

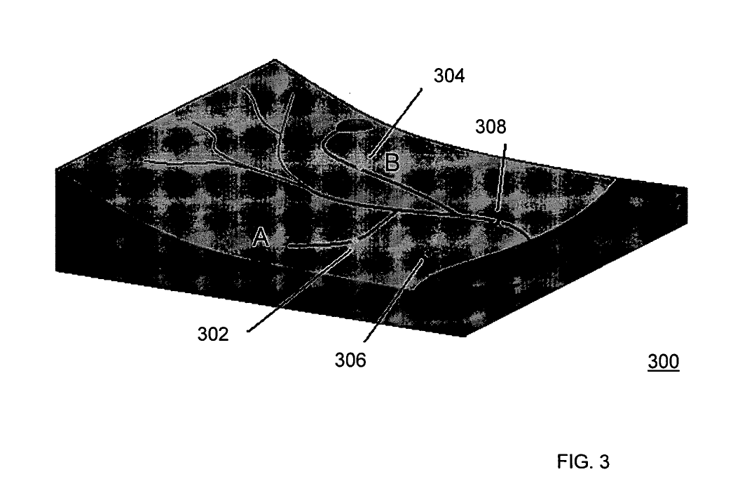

The above may be better explained by reference to an example. Accordingly referring to FIG. 3 there is shown a schematic of a typical watershed 300 having two tributaries A and B. Water level data for the tributaries is received from respective water level gauges 302, 304, and rainfall data is received from a nearby meteorological station 306. If data collected at the tributary B gauging station 304 is to be validated, then all the redundant information possible must be found. Since the main stem 308 and tributary B are both responding to the same macro- (and possibly micro-) scale meteorological forcing, a model (be it linear, dynamic, or nonlinear) can be built that relates the gauge height on the main stem 308 to the stage height on tributary B. Further, a statistical or physical rainfall-runoff model could be built relating tributary B stage to precipitation measured at the meterological station 306. Presuming that a control time series are accurate and the model relating these to the target time series is reliable, there is now a threefold analytical redundancy for the gauge station on tributary B: The main stem stage model, the rainfall-runoff model, and of course the data from the gauge on tributary B.

Returning to the above equations the following can be determined:

$${v}^{T} [ \begin{matrix}{m}_{TribB} \\ {m}_{rain \text{-} fall} \\ {m}_{mod A}\end{matrix} ] = {v}^{T} [ \begin{matrix}1 \\ 1 \\ 1\end{matrix} ] x + {v}^{T} [ \begin{matrix}{ɛ}_{1} \\ {ɛ}_{2} \\ {ɛ}_{3}\end{matrix} ] \qquad ( 7 )$$

The transfer coefficient H is a vector of length three since there is a threefold redundancy in the system. Now proceeding with computing of the left null space of H:

$${v}^{T} H = {v}^{T} [ \begin{matrix}1 \\ 1 \\ 1\end{matrix} ] = [ {v}_{1} , {v}_{2} , {v}_{3} ] [ \begin{matrix}1 \\ 1 \\ 1\end{matrix} ] = 0 \qquad ( 8 )$$

The rank of H implies that there are two degrees of freedom; thus, v^{T}can be represented as two linearly independent vectors each orthogonal to H=[1 1 1]^{T}. That is:

$$\begin{matrix}\begin{matrix}{v}^{T} = [ \begin{matrix}{v}_{11} & {v}_{12} & {v}_{13} \\ {v}_{21} & {v}_{22} & {v}_{23}\end{matrix} ] \\ = [ \begin{matrix}{v}_{1}^{T} \\ {v}_{2}^{T}\end{matrix} ]\end{matrix} & ( 9 )\end{matrix}$$

At this point there are six unknowns:

v₁₁,v₁₂,v₁₃,v₂₁,v₂₂,v₂₃ (10)

We have two equations from the left null space:

v₁₁+v₁₂+v₁₃=0

v₂₁+v₂₂+v₂₃=0 (11)

Additionally choosing v₁^{T}⊥v₂^{T} gives one more equation:

v₁₁v₂₁+v₁₂v₂₂+v₁₃v₂₃=0 (12)

Choosing to impose normalcy, |v₁^{T}|=1 and |v₂^{T}|=1, gives a further two equations:

v₁₁²+v₁₂²+v₁₃²=1

v₂₁²+v₂₂²+v₂₃²=1 (13)

Now having two normal unit vectors v₁^{T} and v₂^{T} spanning the left null space of H, still leaves only five equations and six unknowns. Arbitrarily setting one value to zero to find a solution i.e. set v₂₁=0 then:

$${v}^{T} = [ \begin{matrix}\sqrt{\frac{2}{3}} & - \sqrt{\frac{1}{6}} & - \sqrt{\frac{1}{6}} \\ 0 & \sqrt{\frac{1}{2}} & - \sqrt{\frac{1}{2}}\end{matrix} ] \qquad ( 14 )$$

The parity vector equation can be formulated by combining equation (14) and equation (5).

$$( 15 )$$

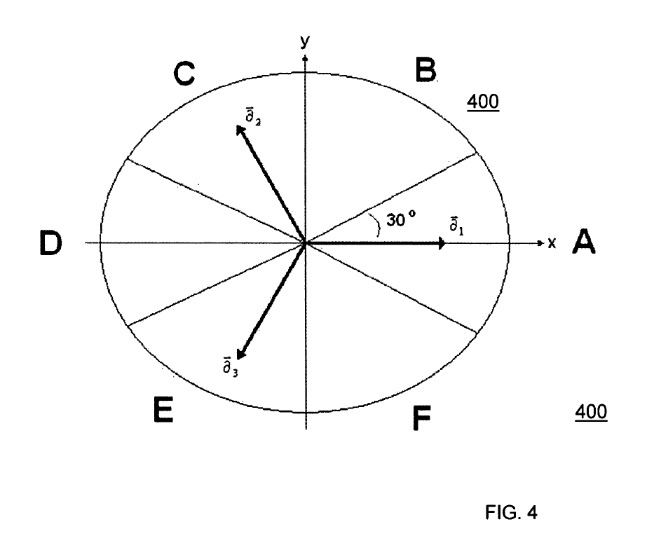

Thus the parity vector [symbol] , and the error directional vectors \vec{∂}₁, \vec{∂}₂, and \vec{∂}₃ are defined. These error directional vectors are non-orthogonal vectors lying in the parity space. Although they are non-orthogonal they are maximally independent. Referring now to FIG. 4 there is shown a planar plot 400 of the three vectors \vec{∂}₁, \vec{∂}₂, and \vec{∂}₃ maximally spaced in a 2D space and where the symbols A to F represent regional sectors in a unit circle.

Computing and plotting the parity vector [symbol] for a given instant in the time series, and then plotting the three error directional vectors \vec{∂}₁, \vec{∂}₂, and \vec{∂}₃, can visually identify the primary source of the error for this measurement. This can be shown graphically in FIG. 4, if the parity vector [symbol] lies in region A or D, then the \vec{∂}₁ direction dominates, implying the ε₁ term is large relative to ε₂ and ε₃. Similarly, if the parity vector lies in the region C or F, ε₂ dominates; or in regions B or E, ε₃ dominates. This can also be done analytically without plotting the vectors.

Using this information, if interested in validating the data collected at the tributary B gauging station, the parity vectors lying only in regions A and D need be considered since regions A and D are those dominated by \vec{∂}₁, the error direction associated with tributary B (see above). With higher levels of analytical redundancy, and thus more error directions, the parity space quickly expands to higher dimensions. The dimension of the parity space is equal to the order of redundancy (three, in this example) minus one (a result of H^{T}=[1 1 . . . 1] being a rank one matrix). When dealing with a parity hyperspace, the regions of interest for validating a single signal can be computed by calculating the angle between each parity vector and each error direction. The error direction with which a parity vector makes the smallest angle provides the dominant error direction for this parity vector. By grouping all the parity vectors for which a given error direction dominates we can construct a selected set (or in a specific instance a manifold) of parity vectors for errors associated with the signal to be validated. The angle between any parity vector [symbol] and the subspace defined by any error direction \vec{∂} can be computed in any dimension by the inner product:

$$θ = arccos ( \frac{\vec{℘} \cdot \vec{\partial }}{\vert \vec{℘} \vert \cdot \vert \vec{\partial } \vert} ) \qquad ( 17 )$$

The applicants of the present invention have discovered that the distribution of the parity vector magnitudes, [symbol] , for parity vectors dominated by the error direction of the signal being validated, can be modelled using a suitable distribution function such as the gamma distribution. Moreover, in cases of very high redundancy, the summation of random variables (since

$$\vert \vec{℘} \vert = \sqrt{{\sum }_{i} {℘}_{i}^{2}} ,$$

where [symbol] is a random variable representing the i^{th} component of [symbol] ) invokes the central limit theorem: that is, the distribution of [symbol] is asymptotically Gaussian. The gamma distribution is able to very closely approximate a Gaussian distribution, but is also able to characterize the skewed distributions encountered at much lower orders of redundancy, which is, the case most often encountered in water quality monitoring.

Using maximum likelihood estimators, it is possible to solve for the gamma distribution parameters a and b for a given dataset. From the resulting fitted gamma distribution, each parity vector [symbol] within the subset can be translated to a percentile from 0 to 100%:

$$p = f ( x \leq {x}^{*} \vert a , b ) = \frac{1}{{b}^{a} Γ ( a )} {\int }_{0}^{x} {t}^{a - 1} {e}^{\frac{t}{b}} d t \qquad ( 18 )$$

The percentile provides an estimate of the probability that the current value of the time series being validated is in error. Thus, high percentiles indicate data that are not corroborated by the analytic or physical redundancy of our system, whereas lower percentiles suggest data congruent with redundant information.

At this point it should be noted that percentiles can only calculated here for 1/k^{th} of the data within the section of data being validated, where k is the level of redundancy (both physical and analytic). Note that typically, one section of data at a time will be validated; data collected between site visits, since the last validation exercise, over a season, or a walking window of data points for real-time applications, for example. Statistically, the larger the level of analytic or physical redundancy, the fewer good data will appear within the space or set of parity vectors maximally aligned with the error direction of interest. For calculation of the gamma distribution parameters a and b, good data (parity vectors of small magnitude) must be far more numerous than bad data (large magnitude parity vectors). That is, equation (19) must hold or the normal noise and measurement discrepancy between sensors will not be able to dominate the calculation distribution parameters.

k·n_{good}<<n_{bad} (19)

Here n_{good} is the number of good data points, n_{bad} is the number of poor data points, and k is the order of redundancy in the validation model. If this condition is not met a larger sample of data must to be validated.

It should be further noted that data in a given signal that is incongruent with redundant signals are drawn into the set of parity vectors maximally aligned with that given signal's error direction. In the case of data corruption, the coefficient of the \vec{∂} error direction is large compared to the other error direction coefficients. This domination by a single error direction necessitates that the parity vector for a data corruption lies within the set making a minimum angle with the error direction in question. This ensures that the method of parity space validation is not prone to overlooking erroneous data. The exception to this is when two simultaneous corruptions exist, one in the signal of interest and one in a redundant signal. When two error direction coefficients are large the parity vector may in fact be drawn into neither maximally aligned set (a consequence of error directions not being orthogonal). For example, if for a given parity vector the coefficients of both \vec{∂}₂ and \vec{∂}₃ are large then the parity vector will appear in region D, implying an error in signal 1, when in fact the errors were in signals 2 and 3.

The foregoing considerations behoove the data validator to choose a small number of representative and accurate redundant signals and sensors, rather than many poor redundant signals and to select a large window for data validation. Also need to ensure that if analytical redundancy is employed, to ensure that the model relating the target to the redundant signals is of high quality and adequately captures all phenomena that may substantially influence the target signal's behaviour (the latter may be difficult in the case of, for example, unauthorized industrial point discharges). That is, strictly speaking, the parity space method estimates only the congruency or mutual consistency of the target and redundant signals. If the redundant data, and the model (if used) relating the redundant data to the target data, are both of sufficiently high quality then the redundant data serve as one or more control signals. In this case, data congruency may be taken to indicate high-quality target data.

Returning to percentiles estimated using the gamma distribution, data validation flags can be assigned based on percentiles. Since the interesting region of the distribution lies from about the 80^{th} percentile to the 100^{th} percentile it is beneficial to visualize the percentiles through percentile bins—for example 0 to 80, 80 to 95, 95 to 99, 99 to 100 and each range if displayed in a user interface they may be designated by a different colour.

Percentile validation flags are based on statistical confidence, rather than being parameter-specific thus simplifying and generalizing the data validation process. The ability to quickly run through often immense data sets and flag data that are incongruent with model or redundant information allows the data manager to focus his or her attention on specific regions of data that are either erroneous or the results of abnormal watershed conditions.

The above data validation method can be used to determine dissolved oxygen data from a large river system and more particularly for determining dissolved oxygen sensor drift. If a method can identify when a drift begins and the severity of the sensor's divergence from optimal operation, it would allow data managers to flag only erroneous regions of data rather than masking all data between when the sensor was discovered to be damaged, and the most recent time the sensor was known to be operating correctly (usually the previous site visit).

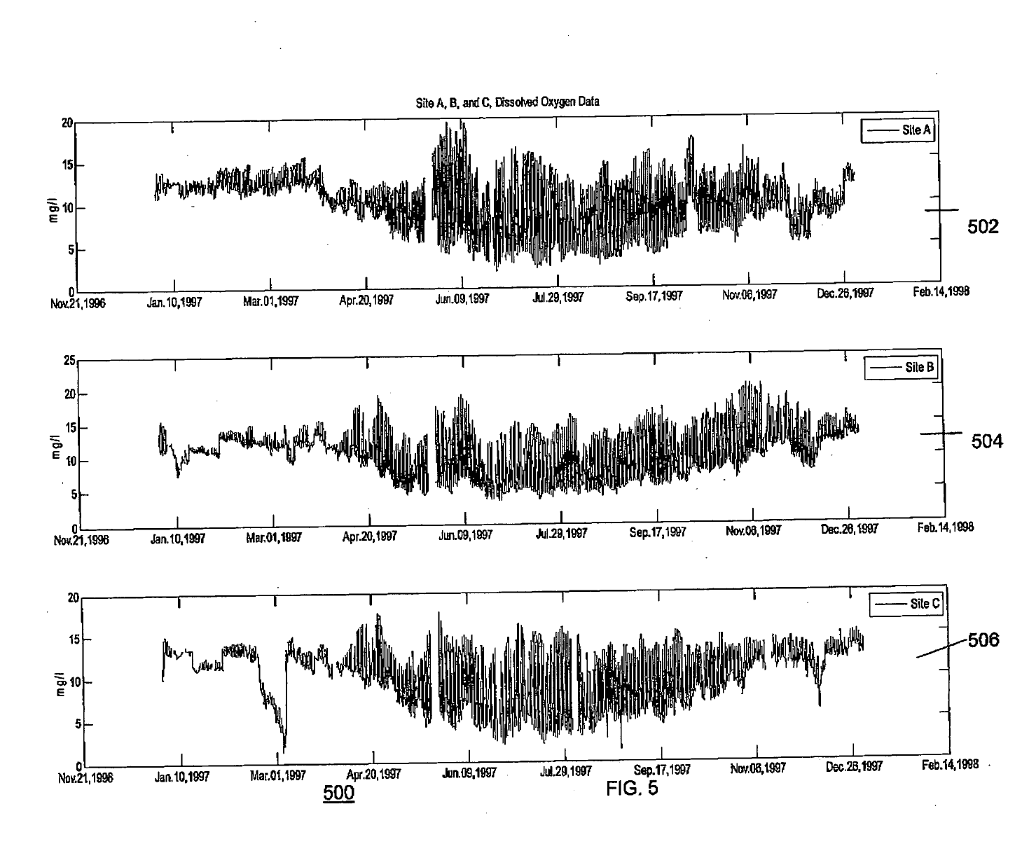

Referring now to FIG. 5 there is shown graphs 500 of data over a period of time from three dissolved oxygen sensors 502, 504, 506 from a watershed in southern Ontario. All three sensors were positioned along the same river system and are here referred to as Site A, B and C. There is a potential sensor drift in the Site C data 506 spanning Mar. 1, 1997. Additionally there were other data anomalies such as data spikes and gaps throughout all three time series.

The diurnal oscillation of dissolved oxygen observed in this eutrophic system is in part a biological process for this watershed, resulting from photosynthesis and organic matter decay. Stations with morning vs. afternoon direct sunlight show a phase difference. To compensate for this process adjustment to the phase of both redundant signals (Site A and Site B) to maximize their linear correlation with the Site C signal was made. In addition to phase adjustment the signals from site A and B were adjusted using a linear model to account for amplified or attenuated diurnal processes at each sensor location.

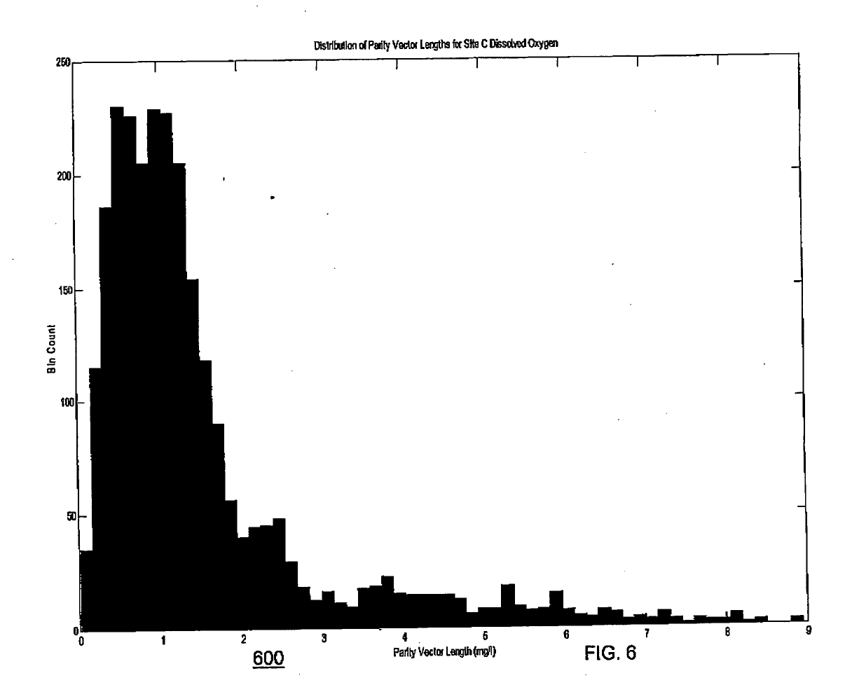

The parity space vectors were calculated using the other sensors, Site A and Site B, as physical (albeit phase-adjusted, and amplified or attenuated) redundant signals. After selecting those parity vectors that are principally influenced by the Site C error direction, the distribution of parity vector lengths 600 was generated as shown graphically in FIG. 6. Evaluating magnitudes of the parity vectors within this set (the selected vectors), and proceeding on the assumption that the phase-shifted Site A and B signals provide sufficient analytical redundancy, data validation flags were computed for the Site C dissolved oxygen signal based on percentiles of a fitted gamma distribution.

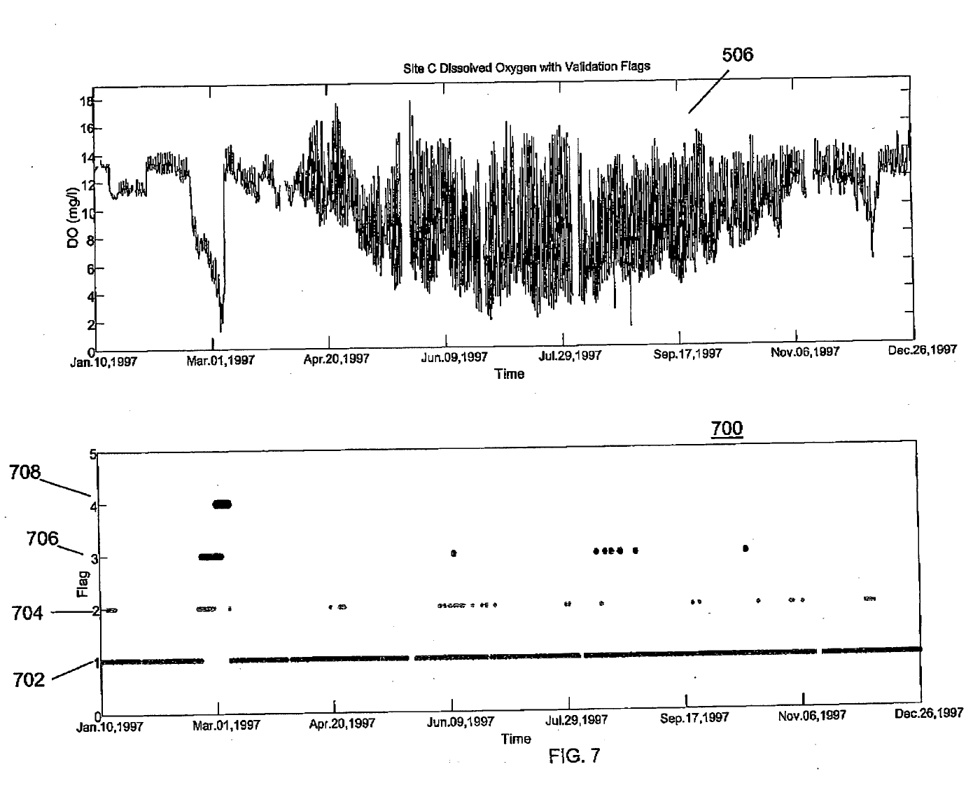

Referring to FIG. 7, there is shown generally by the numeral 700 the data series for the site C along with the validation flags as generated by the above method. The data validation flags were constructed using the 0 to 80^{th} percentiles 702, the 80^{th} to 95^{th} percentiles 704, the 95^{th} to 99^{th} percentiles 706, and the 99^{th} to 100^{th} percentiles 708. In FIG. 7 the different flags are plotted on the lower graph with the values 1, 2, 3, and 4 representing the percentile ranges.

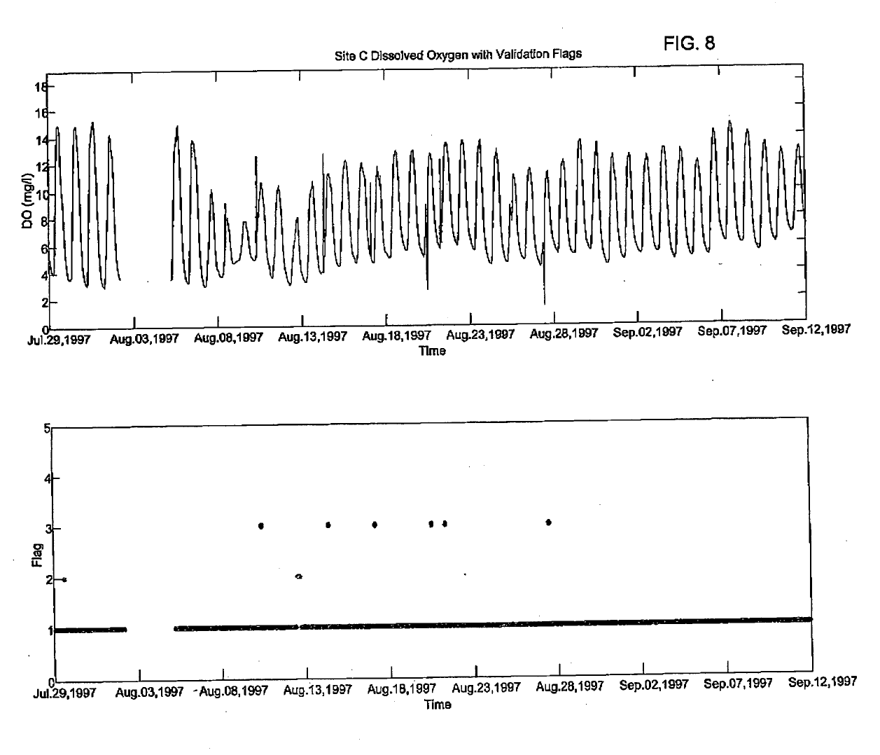

The method correctly identifies the drifting sensor at Site C with progressively more serious flags. Additionally the method identifies several outliers that lay with the diurnal range of the Site C signal during August 1997. An expanded plot of the outliers and corresponding data flags is shown in FIG. 8. The method was able to identify outliers in the Site C dissolved oxygen signal despite the outlier values falling within physically plausible range and additionally within the diurnal range of the signal.

Automated water quality and quantity monitoring allows scientists and managers high-resolution information to characterize an aquatic system. With these data comes the responsibility to assure their quality before action is taken or data are disseminated to the public. The method of probabilistic parity space data validation described offers water scientists and data managers a tool to quickly highlight particular regions of (often vast) data series that must be further examined for quality control. Point by point data flags can be assigned to a data series. Furthermore, data flagging can be based on an independent set of intuitive percentile thresholds, rather than complex parameter-specific thresholds. Alternatively, if tolerance ranges for sensor performance have already been established or wish to be used, they can be adapted to provide point by point data flags by applying these tolerances directly to the parity space; a result possible since we do not normalize parity vectors and since the parity matrix is a unity operator. This method, although here only applied to freshwater data series, is equally applicable to marine, atmospheric or any other environmental time series for which redundancy (physical or analytic) can be established. In general the present parity space method can be used as a more general approach for identifying data anomalies on the basis of incongruency with redundant time series.

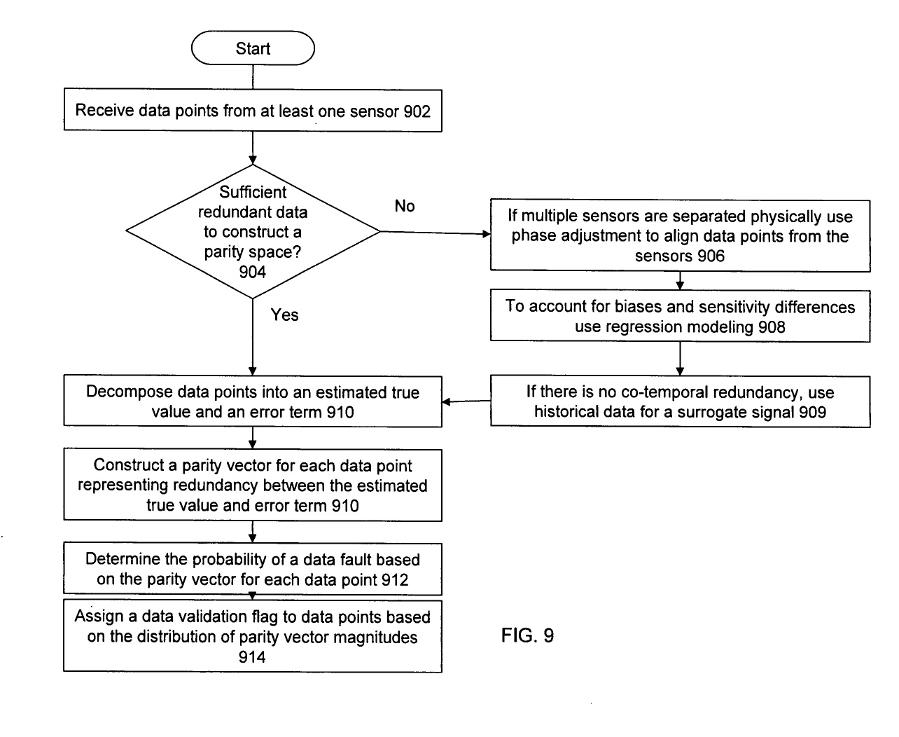

Referring to FIG. 9 there is shown a flow chart of the data validation process 900 according to an embodiment of the invention. The steps can be summarized as follows: Receive data points from at least one sensor 902, determine if there is sufficient redundant data to construct a parity space 904. If multiple sensors are separated physically use phase adjustment to align data points from the sensors 906. to account for biases and sensitivity differences use regression modeling 908, if there is no co-temporal redundancy, use historical data for a surrogate signal 909, next decompose data points into an estimated true value and an error term 910 and construct a parity vector for each data point representing redundancy between the estimated true value and error term 910. Determine the probability of a data fault based on the parity vector for each data point 912, assign a data validation flag to data points based on the distribution of parity vector magnitudes 914

It is appreciated that a lesser or more equipped computer system than the example described above may be desirable for certain implementations. Therefore, the configuration of the system 100 will vary from implementation to implementation depending upon numerous factors, such as price constraints, performance requirements, technological improvements, and/or other circumstances.

Although a programmed processor, such as processor 102 may perform the operations described herein, in alternative embodiments, the operations may be fully or partially implemented by any programmable or hard coded logic, such as Field Programmable Gate Arrays (FPGAs), TTL logic, or Application Specific Integrated Circuits (ASICs), for example. Additionally, the method of the present embodiment may be performed by any combination of programmed general-purpose computer components and/or custom hardware components and may even be combined with sensors. Therefore, nothing disclosed herein should be construed as limiting this disclosure to a particular embodiment wherein the recited operations are performed by a specific combination of hardware components.

Although the invention has been described with reference to certain specific embodiments, various modifications thereof will be apparent to those skilled in the art without departing from the spirit and scope of the invention as outlined in the claims appended hereto.

We claim:

1. A method for identifying anomalies in time series data, said method comprising the steps of:
(a) computing parity vectors for one or more data points in a predetermined sample of data points in said time series, the parity vector representing redundancy between an estimated true value and an error term for each of said one or more data points;
(b) evaluating said parity vectors to determine a set of said parity vectors in a selected direction; and
(c) evaluating a statistical distribution of said set according to a predetermined criterion to determine a data point anomaly to be corrected whose parity vectors satisfy said criterion in said distribution.

2. A method as defined in claim 1, said selected direction being determined by the time series data under consideration.

3. A method as defined in claim 1, said distribution being based on a magnitude of said parity vectors.

4. A method as defined in claim 1, said distribution being based on projections of said parity vectors.

5. A method as defined in claim 3, said magnitude of said set of parity vectors being computed from a physical or analytical redundant network of sensors.

6. A method as defined in claim 1, wherein a phase lag or lead between time series data from the sensors in a network is removed before computation of the parity vectors.

7. A method as defined in claim 1, wherein one or more of attenuation, bias, and amplification of time series from sensors in a network is normalized before the computation of parity vectors.

8. A method as defined in claim 1 wherein the set of relevant parity vectors is chosen based on the criteria of a minimal angle between the parity vector and the error direction vectors defined by a parity matrix.

9. A method as defined in claim 1, wherein the statistical distribution is a Gamma distribution.

10. A method as defined in claim 1, wherein the identification criterion of anomalies is based on percentiles of said statistical distribution.

11. A method as defined in claim 1, wherein the identification criterion of anomalies is based on one or more ranges of the empirical distribution of parity vector lengths.

12. A system for identifying anomalies in time series data, said system comprising:
(a) a first module for computing parity vectors for a data points in a predetermined sample of data points in said time series, the parity vector representing redundancy between an estimated true value and an error term for each said data points;
(b) a second module for evaluating said parity vectors to determine a set of said parity vectors in a selected direction; and
(c) a third module for evaluating a statistical distribution of said set according to a predetermined criterion to determine a data point to be corrected whose parity vectors satisfy said criterion in said distribution.

13. A system as defined in claim 12, including a graphical user interface for displaying said statistical distribution.

14. A system as defined in claim 13, said graphical user interface for displaying a flag with said data points to be corrected.

15. A system as defined in claim 14, said flags being visually coded to signify percentile distribution of said data points to be corrected.

16. A system comprising:
(a) a network of sensors, for sensing one or more environmental conditions and at least one sensor in the network generating at least one time series data sequence;
(b) a data validation module associated with at least one sensor in the network for validating the time series data generated by the at least one sensor, by determining a distribution of parity vectors computed on said time series data points and by using redundant data obtained from the network, the distribution being used to identify data points to be validated in the time series.

17. A computer-readable storage medium having stored therein a program which executes the steps of:
(a) computing parity vectors for a data points in a predetermined sample of data points in a time series, the parity vector representing redundancy between an estimated true value and an error term for each said data points;
(b) evaluating said parity vectors to determine a set of said parity vectors in a selected direction; and
(c) evaluating a statistical distribution of said set according to a predetermined criterion to determine a data point to be corrected whose parity vectors satisfy said criterion in said distribution.
